(19) United States
(12) Patent Application Publication
(10) Pub. No.: US 2025/0261484 A1
(43) Pub. Date: Aug. 14, 2025

(54) MICRO-LED CHIP, AND PREPARATION METHOD AND USE THEREOF

(71) Applicant: SUZHOU INSTITUTE OF NANO-TECH AND NANO-BIONICS (SINANO) , CHINESE ACADEMY OF SCIENCES, Suzhou (CN)

(72) Inventors: Xiaodong ZHANG, Suzhou (CN); Qiang ZHA, Suzhou (CN); Xianhai XIA, Suzhou (CN); Zhongming ZENG, Suzhou (CN); Baoshun ZHANG, Suzhou (CN)

(73) Assignee: SUZHOU INSTITUTE OF NANO-TECH AND NANO-BIONICS (SINANO) , CHINESE ACADEMY OF SCIENCES, Suzhou (CN)

(21) Appl. No.: 18/701,261

(22) PCT Filed: Jun. 19, 2023
(86) PCT No.: PCT/CN2023/101034

§ 371 Date: Apr. 15, 2024

(30) Foreign Application Priority Data
May 22, 2023 (CN) 202310580092.4

(51) Int. Cl. H10H 20/821; H01L 25/16; H10H 20/01; H10H 20/833; H10H 20/857

(52) U.S. Cl. CPC H10H 20/821; H01L 25/167; H10H 20/0364; H10H 20/833; H10H 20/857

(57) ABSTRACT

The Micro-LED chip includes an LED chip structure and a first metasurface conductive structure layer. The first metasurface conductive structure layer includes: a first conductive layer electrically bound to the light emergence face of the LED chip structure; and a metasurface structure which is configured to be stacked and/or integrated with the first conductive layer; wherein the metasurface structure is at least used for regulating the emergence angle or wavelength of light ejected from the light emergence face. Based on the technical solution of the present application, the full colorization of the Micro-LED chip can be realized, the light extraction rate and collimation can be increased, and large-scale standard semiconductor processes can be adopted to realize the preparation of the Micro-LED chip and the integration of Micro-LED pixels and display units, thereby improving the production efficiency and yield rate of the Micro-LED chip and reducing the cost.

### CROSS REFERENCE TO THE RELATED APPLICATIONS

This application is the national phase entry of International Application No. PCT/CN2023/101034, filed on Jun. 19, 2023, which is based upon and claims priority to Chinese Patent Application No. 202310580092.4, filed on May 22, 2023, the entire contents of which are incorporated herein by reference.

### TECHNICAL FIELD

The present application relates to a semiconductor optoelectronic device, and in particular to a Micro-LED chip, and a preparation method and use thereof, and belongs to the field of semiconductor optoelectronic technology.

### BACKGROUND

A Micro-LED (micro-light emitting diode) has excellent performance in terms of brightness, contrast, luminous efficiency, resolution, response speed, energy consumption, impact resistance, operating temperature and service life, is an indispensable technology in the new-generation display field, and has broad application prospects in ultra-high-definition large-screen displays, micro-display screens, flexible display screens, head-mounted displays, augmented and virtual reality, etc. In the current application of display technology, LED-based display technology plays an important role in people's lives. Among them, the new gallium nitride (GaN) Micro-LED display technology is one of the most potential display technologies and will probably replace other display technologies gradually and become the final mainstream technology in the display field.

A GaN LED active region has luminescent characteristics of isotropy, in which light is emitted in all directions, and the light divergence angle is relative larger, so very little light actually emerges from an emission window, seriously affecting the effective luminous efficiency of the LED. In the most common display field, larger viewing angles as well as saturation and contrast of light are required, and in the field of industrial exposure and image projection, the numerical aperture of the projection lens is limited, which requires the light emitted by Micro-LED devices and arrays thereof to have a smaller divergence angle, higher light extraction efficiency and higher luminous quality.

Currently, the solutions used for improving the light extraction efficiency and light extraction direction of Micro-LEDs mainly include a resonant cavity structure, a lens system, etc. The resonant cavity structure is a structure in which two reflective structures are prepared at the bottom and top of the Micro-LED active region, a micro-cavity structure is formed so that the light emitted from the active region is reflected back and forth under the action of the resonant cavity to achieve constructive interference, thereby enhancing the light-emitting efficiency and collimation of the light emitted by the active region to achieve enhancement of the optical characteristics of the device. However, this solution has a complex process and the bottom preparation process has large difficulty. It needs to remove the Micro-LED material from the original substrate before the bottom reflective layer can be increased, which is only suitable for a Micro-LED device structure having a peel-off structure. A lens system mainly changes the optical path of the emitted light through a specific micro-lens to improve the luminous collimation of the device. However, its preparation is very difficult and generally requires complex photolithography, etching and the like processes before the lens system is added on the top of the Micro-LED. Moreover, the lens system has a large volume, is not suitable for lightweight applications, and has high cost.

On the other hand, in the colored display application of the Micro-LED, wavelength conversion of a monochromatic wavelength Micro-LED is usually required. Currently, common solutions mainly include mass transfer and quantum dot film color conversion, etc. Among them, the mass transfer technology requires the use of mechanical transfer and the like manners to place Micro-LED units of different colors on the same substrate. Since the extremely high pixel density and extremely large transfer volume generally requires to be completed by special-purpose large-scale equipment, and the requirement on the control accuracy of the adsorption and placement of Micro-LED pixels during the transfer process is extremely high, the success rate of adsorption during the transfer process directly affects the product yield. Moreover, the pixel spacing is relatively larger after the transfer and placement, which is not suitable for ultra-high-resolution display applications. Quantum dot color conversion technology generally uses quantum dot films such as zinc sulfide, cadmium selenide, and perovskite to convert the blue light emitted by conventional GaN Micro-LEDs into green and red light, so as to achieve color conversion. However, the existing quantum dot technology is not mature enough. It is very difficult to control the scale uniformity of quantum dots, and scale variation will affect the purity of the color. Meanwhile, existing quantum dots are generally difficult to withstand high temperatures, so they must be thermally insulated from the Micro-LED chip; issues such as ensuring the uniformity of each color during the spraying process and avoiding mutual interference among quantum dots of different colors also need to be further addressed. Moreover, quantum dots are all prepared by using chemical methods and are not environmentally friendly.

### SUMMARY

A main objective of the present application is to provide a Micro-LED chip, and a preparation method and use thereof, so as to overcome the shortcomings of the prior art.

In order to achieve the aforementioned application objective, the technical solutions adopted in the present application include the follows.

One aspect of the present application provides a Micro-LED chip, which includes an LED chip structure and a first metasurface conductive structure layer, wherein the first metasurface conductive structure layer includes:
a first conductive layer which is electrically bonded to a light emergence face of the LED chip structure; and
a metasurface structure which is configured to be stacked and/or integrated with the first conductive layer, and is at least used for regulating the emergence angle and/or wavelength of the light ejected from the light emergence face.

Another aspect of the present application provides a method for making the Micro-LED chip, which includes:
making a LED chip structure; and
disposing a first conductive layer and a metasurface structure on the light emergence face of the LED chip structure, wherein the metasurface structure is configured to be stacked and/or integrated with the first conductive layer.

A further aspect of the present application provides use of the Micro-LED chip in preparation of an optoelectronic device, wherein the optoelectronic device includes but is not limited to a display device, a micro-display device, and the like.

Compared with the prior art, the present application integrates metasurface structures into a Micro-LED chip, which can not only give full play to the excellent performance of the GaN-based Micro-LED, but also realize full colorization of the Micro-LED simply and at low cost, and significantly increase the light extraction rate and collimation of the chip. Meanwhile, the preparation of the Micro-LED chip and the integration of Micro-LED pixels with display units can be achieved through large-scale standard semiconductor processes, effectively improving the production efficiency and yield rate of the Micro-LED chip and significantly reducing the cost of the chip, which is conducive to promoting the development and application of the Micro-LED in display fields.

### BRIEF DESCRIPTION OF THE DRAWINGS

The accompanying drawings of the specification which form a part of the present application are used for providing further understanding of the present application. The illustrative embodiments of the present application and the description thereof are used for explaining the present application, and do not constitute improper limitation of the present application.

FIG. 1 is a schematic structural diagram of a Micro-LED chip in Example 1;

FIG. 2 is a schematic diagram of a first metasurface conductive structure layer in Example 1;

FIG. 3 is a schematic structural diagram of an epitaxial wafer of a Micro-LED chip in Example 1;

FIG. 4 is a schematic diagram of a first metasurface conductive structure layer in Example 4;

FIG. 5 is a schematic diagram of a first metasurface conductive structure layer in Example 8;

FIG. 6 is a schematic structural diagram of a Micro-LED chip in Example 10;

FIG. 7 is a schematic diagram of a first metasurface conductive structure layer in Example 11;

FIG. 8 is a schematic diagram of a third metasurface structure in Example 12;

FIG. 9 is a schematic structural diagram of a Micro-LED chip in Example 13;

FIG. 10 is a partially enlarged schematic diagram of a region A in FIG. 9; and

FIG. 11 is a diagram showing a test of the reflectivity of a thermally conductive dielectric layer for light of different wavelengths in Example 12.

### DETAILED DESCRIPTION OF THE EMBODIMENTS

In the present application, a metasurface structure is integrated into a Micro-LED chip, especially a conductive metasurface structure is disposed on a light emergence face of the Micro-LED chip, thereby optimizing its light emergence angle, improving its light extraction efficiency, and reducing the process difficulty and cost of its colorization. The technical solution of the present application will be described in further detail below.

In this specification, the metasurface structure is a two-dimensional planar figure composed of materials with special electromagnetic properties in a certain arrangement, which is mainly composed of sub-wavelength nanometer-sized microstructural units, and can achieve flexible regulation of the amplitude, phase, polarization, and the like of the incident light.

Some embodiments of the present application provide a Micro-LED chip, which includes an LED chip structure and a first metasurface conductive structure layer, wherein the first metasurface conductive structure layer includes:
a first conductive layer which is electrically bonded to a light emergence face of the LED chip structure; and
a metasurface structure which is configured to be stacked and/or integrated with the first conductive layer, and is at least used for regulating the emergence angle and/or wavelength of the light ejected from the light emergence face, thereby at least achieving one or more of the following effects, including: optimizing the collimation of the light emitted by the Micro-LED chip, improving the light extraction efficiency of the Micro-LED chip, and changing the color of the light emitted by the Micro-LED chip.

In one embodiment, the metasurface structure includes a first metasurface structure, the first conductive layer includes a plurality of first pattern structures which are distributed in a direction parallel to the light emergence face and form the first metasurface structure; wherein the first conductive layer includes a metal or non-metal conductive layer.

Further, the metal conductive layer can have a thickness below 20 nm, and has the first metasurface structure. The first metasurface structure can not only make the metal conductive layer have better light transmittance, but also play a role in regulating the emergence angle and/or wavelength of light, and meanwhile can also form an array of electrodes. For example, the metal conductive layer can have a thickness of 0.1, 1, 2, 3, 4, 5, 6, 7, 8, 9, 10, 11, 12, 13, 14, 15, 16, 17, 18, 19 or 20 nm to give it good light transmittance.

Further, the metal conductive layer can have a thickness greater than 20 nm, and has the first metasurface structure, so that on one hand, the metal conductive layer has better current expansion capabilities, and on the other hand, the first metasurface structure is utilized to maintain good light transmittance, while allowing the first metasurface structure to fully exert its ability to regulate the emergence angle and/or wavelength of the light, and improve at least one of the light extraction efficiency, collimation and full colorization performance of the Micro-LED chip. Moreover, an array of electrodes can also be formed, and each electrode in the array corresponds to a corresponding light-emitting pixel point, which is conducive to precise regulation of the light field of each pixel unit.

In particular, when the first conductive layer is a metal layer, and the first pattern structure has a nanoscale size, the first pattern structure also exhibits a very strong light field localized surface plasmon resonance effect as a metal nanostructure, so that when the light emitted by the LED chip structure is incident on the first conductive layer, and the frequency of the light matches the vibration frequency of the conductive electrons of the metal nanostructure, the first pattern structure will produce a strong absorption effect on the energy of the photons, and exhibits a very strong resonance absorption peak on the spectrum. Furthermore, while a plurality of the first pattern structures form the first metasurface structure, since the metal nanostructure has a plasmon resonance effect, and these metal nanostructures are arranged relatively compactly, mutual coupling will occur between the nanostructures, making the overall resonance intensity stronger, and ultimately making the color rendering efficiency of the Micro-LED chip higher.

In one embodiment, the first conductive layer includes a metal or non-metal conductive layer; the metal conductive layer has a thickness below 20 nm and extends continuously in a direction parallel to the light emergence face.

Further, the material of the metal conductive layer includes a combination of any one or more of indium, tin, silver, platinum, gold, titanium, aluminum, nickel, chromium, molybdenum and copper, but is not limited thereto.

In one embodiment, the material of the non-metal conductive layer includes ITO (indium tin oxide) or other transparent conductive materials, such as graphene, carbon nanotubes, conductive polymers, etc. or a combination thereof, but is not limited thereto.

In one embodiment, the thickness of the non-metal conductive layer is 1 nm-500 nm.

Further, in a direction parallel to the light emergence face, the dimension of the first pattern structure is 0.1 nm-1 μm, preferably 80 nm-800 nm, and more preferably 100 nm-600 nm.

Further, the first pattern structure comprises an X-shaped pattern structure and a variant Y-shaped pattern structure; in a specified direction parallel to the light emergence face, and the variant Y-shaped shape is a shape formed by rotating a Y shape by 90° clockwise; and the X-shaped pattern structure and the variant Y-shaped pattern structure are alternately arranged along the specified direction, and each X-shaped pattern structure and a Y-shaped pattern structure adjacent thereto are spaced 1-500 nm apart from each other and forms a unit, multiple units are periodically arranged, and the periods in the specified direction and the direction perpendicular to the specified direction are both 1 nm-1 μm. Preferably, the X-shaped pattern structure and the Y-shaped pattern structure in one unit are spaced 10-100 nm, and more preferably 30-50 nm apart from each other. Preferably, the period is 50-500 nm, and more preferably 100-300 nm. The dimension of the first pattern structure is preferably 450 to 550 nm particularly.

In some instances, the plurality of first pattern structures included in the first metasurface structure may also be the same. The first metasurface structure may also be a non-periodic structure. However, it is preferred to adopt the aforementioned X-shaped pattern structure, the variant Y-shaped pattern structure and the periodic arrangement manner.

In one embodiment, the first metasurface conductive structure layer further includes a transparent dielectric layer stacked on the first conductive layer.

In one embodiment, the metasurface structure includes a second metasurface structure, the transparent dielectric layer includes a plurality of second pattern structures, and the plurality of second pattern structures are distributed in a direction parallel to the light emergence face and form a second metasurface structure.

Further, in a direction parallel to the light emergence face, the dimension of the second pattern structure is 1 nm-1 μm, preferably 50 nm-900 nm, and more preferably 50 nm-500 nm.

In some instances, the second pattern structure includes a circular pattern structure with a variant F-shaped through hole embedded in the center thereof, and in a specified direction parallel to the light emergence face, the variant F shape is a shape formed by rotating a F shape by 30° clockwise, the dimension of the variation F-shape is 1-200 nm, preferably 10-100 nm, and more preferably 10-50 nm, a plurality of circular pattern structures are arranged periodically, and the periods in the specified direction and the direction perpendicular to the specified direction are both 1 nm-1 μm, preferably 5-300 nm, and more preferably 10-100 nm. Particularly preferably, the diameter of the circular pattern structure is 50-150 nm.

Alternatively, in some instances, the second pattern structure includes a variant K-shaped pattern structure and a variant L-shaped pattern structure, in a specified direction parallel to the light emergence face, the variant K-shaped shape is formed by rotating a K shape by 45° counterclockwise, the variant L-shape is a shape formed by flipping a L shape in a mirror image manner, the variant K-shaped pattern structure and the variant L-shaped pattern structure are alternately arranged along the specified direction, each of the variant K-shaped pattern structures and one variant L-shaped pattern structure adjacent thereto is spaced 1-200 nm (preferably 10-100 nm, and more preferably 10-50 nm) apart from each other and forms a unit, a plurality of the units are periodically arranged, and the periods in the specified direction and the direction perpendicular to the specified direction are both 1-500 nm, preferably 50-200 nm, and more preferably 100-200 nm. Particularly preferably, the dimension of the variant K-shaped pattern structure and the variant L-shaped pattern structure is 50-150 nm.

Alternatively, in some instances, the second pattern structure includes a regular hexagonal pattern structure with an H-shaped through hole embedded in the center thereof, the dimension of the H-shaped through hole is 1-200 nm, preferably 10-100 nm, and more preferably 10-50 nm, in a specified direction parallel to the light emergence face every two adjacent regular hexagonal pattern structures are spaced 1-200 nm (preferably 10-100 nm, and more preferably 50-100 nm) apart from each other and form a unit, a plurality of the units are arranged periodically, and the periods in the specified direction and the direction perpendicular to the specified direction are both 1-1,000 nm, preferably 50-500 nm, and particularly preferably 100-200 nm. Particularly preferably, the diameter of the regular hexagonal pattern structure is 50-100 nm.

Alternatively, in some instances, the second pattern structure includes an elliptical pattern structure, the ellipse shape has a long axis dimension of 1-1,000 nm (preferably 50-500 nm, and more preferably 100-200 nm) that is parallel to a specified direction on the light emergence face and a short axis dimension of 1-1,000 nm (preferably 10-500 nm, more preferably 10-200 nm, and particularly preferably 50-100 nm), a V-shaped through hole and an X-shaped through hole are respectively formed on two sides of the short shaft, the dimensions of the V shape and the X shape are 1-500 nm (preferably 10-100 nm, and more preferably 10-50 nm), the V-shaped through hole and the X-shaped through hole are spaced 1-500 nm (preferably 10-200 nm, and more preferably 30-80 nm) apart from each other, each two adjacent elliptical pattern structures are spaced 1-500 nm (preferably 10-200 nm, and more preferably 50-100 nm) apart from each other and form a unit, a plurality of the units are periodically arranged, and the periods in the specified direction and the direction perpendicular to the specified direction are 1-1,000 nm, preferably 10-500 nm, and more preferably 100-200 nm.

Alternatively, in some instances, the second pattern structure includes a variant z-shaped pattern structure, a variant T-shaped pattern structure, a variant M-shaped pattern structure, and a P-shaped pattern structure. The variant z-shaped pattern structure and the variant T-shaped pattern structure are alternately arranged along a specified direction parallel to the light emergence face, the variant M-shaped pattern structure and the P-shaped pattern structure are also alternately arranged along the specified direction, the P-shaped pattern structure and the variant Z-shaped pattern structure are arranged alternately along a direction perpendicular to the specified direction, and the variant M-shaped pattern structure and the variant T-shaped pattern structure are alternately arranged in the direction perpendicular to the specified direction. Each variant z-shaped pattern structure and one variant T-shaped pattern structure, one variant M-shaped pattern structure and one P-shaped pattern structure that are adjacent thereto form a unit, and any two pattern structures in each of the units are spaced 1-200 nm (preferably 10-100 nm, and more preferably 30-80 nm) apart from each other in the specified direction and the direction perpendicular to the specified direction; and a plurality of the units are periodically arranged, and the periods in the specified direction and the direction perpendicular to the specified direction are 1-1,000 nm, preferably 10-500 nm, and more preferably 100-300 nm. Particularly preferably, the dimension of the variant z-shaped pattern structure, the variant T-shaped pattern structure, the variant M-shaped pattern structure and the P-shaped pattern structure is 100-200 nm.

In some instances, the second metasurface structure may also be a non-periodic structure.

In one embodiment, the metasurface structure includes:
a first metasurface structure, which is formed in the first conductive layer and at least used for regulating one of the emergence angle and wavelength of the light ejected from the light emergence face; and
a second metasurface structure, which is at least used for regulating the other one of the emergence angle and wavelength of the light ejected from the light emergence face.

Exemplarily, in a first instance, the first metasurface structure is used for regulating the emergence angle of the light ejected from the light emergence face to improve the collimation of the light ejected from the Micro-LED chip; and meanwhile, the second metasurface structure is used for regulating the wavelength of the light ejected from the light emergence face, i.e., changing the wavelength of the light ejected from the light emergence face, and thus achieving a discoloration effect on the Micro-LED chip. Alternatively, it may also be the second instance, that is, the first metasurface structure is used for regulating the wavelength of the light ejected from the light emergence face, and the second metasurface structure is used for regulating the emergence angle of light ejected from the light emergence face. Surprisingly, compared to the first instance, in the second instance, the structure of the Micro-LED chip can be simpler, the color gamut can be increased while the wavelength color regulation is formed and the emergent brightness is improved, and the color saturation is higher, so that a more uniform observation effect is obtained.

Further, the material of the transparent dielectric layer includes a combination of any one or more of silicon oxide, silicon nitride, aluminum nitride, aluminum oxide, gallium oxide, titanium oxide, and hafnium oxide, and is not limited thereto.

Further, the thickness of the transparent dielectric layer is 0.1 nm-1 μm, preferably 20 nm-600 nm, and more preferably 100-400 nm. In the first instance mentioned above, if the transparent dielectric layer with this more preferred thickness is used, the Micro-LED chip will have higher luminous brightness and color hue saturation, and better luminous uniformity.

In one embodiment, the Micro-LED chip further includes a second metasurface conductive structure layer, wherein the LED chip structure have a first face and a second face opposite to the first face, the first face is the light emergence face, and the second face is electrically bound with a LED driving mechanism through the second conductive layer.

In one embodiment, the second face of the LED chip structure is electrically bound with the LED driving mechanism through a second metasurface conductive structure layer, the second metasurface conductive structure layer includes the second conductive layer and a third metasurface structure, the third metasurface structure is disposed on the side surface of the second conductive layer close to the LED chip structure or the second face of the LED chip structure, and is at least used for reflecting the light emitted by the LED chip structure toward the second metasurface conductive structure layer.

Further, the third metasurface structure includes a plurality of third pattern structures distributed in a direction parallel to the second surface, and in a direction parallel to the second surface, the dimension of the third pattern structure is 1 nm-1 μm, preferably 80 nm-800 nm, and more preferably 150 nm-650 nm.

Further, the third pattern structure includes an equilateral triangle pattern structure and a variant equilateral triangle pattern structure, the equilateral triangle pattern structure and the variant equilateral triangle pattern structure are alternately arranged along a specified direction parallel to the second face, wherein a variant X-shaped through hole is embedded in the center of the equilateral triangle pattern structure, the variant X-shape is a shape obtained by rotating a X shape by 45° clockwise, a variant Z-shaped through hole is embedded in the center of the variant equilateral triangle pattern structure, the variant equilateral triangle is a shape obtained by rotating an equilateral triangle around a designated point by 90° clockwise, the variant Z-shape is a shape obtained by rotating the Z-shape by 45° clockwise, the line length of the variant X-shape and the variant Z-shape is 1 nm-500 nm, preferably 10-200 nm, and more preferably 50-100 nm; the midpoint of one side of each of the equilateral triangle pattern structures and a vertex of an adjacent one of the equilateral triangle pattern structure intersect at the designated point and form a unit., and a plurality of the units are periodically arranged, the period in the specified direction is 1 nm-1 μm, preferably 50-500 nm, and more preferably 100-500 nm, and the period in the direction perpendicular to the specified direction is 1 nm-1 μm, preferably 50-500 nm, and more preferably 100-500 nm.

Further, a plurality of the third pattern structures included in the third metasurface structure are the same or different, and the third metasurface structure is a periodic or non-periodic structure.

Further, the LED driving mechanism can include but is not limited to a CMOS or TFT driving mechanism, etc., which may be integrated with a driving substrate or the like.

Further, the second conductive layer may be made of a metal material, for example a combination of any one or more of indium, tin, silver, platinum, gold, titanium, aluminum, nickel, chromium, molybdenum and copper; or a non-metal material, such as ITO, graphene, carbon nanotubes, conductive polymers, etc., and is not limited to this. Preferably, the second conductive layer is formed of a metal material with good thermal conductivity, electrical conductivity, and light reflective properties, such as aluminum, indium, tin, silver, or gold, and the like metals.

Further, the thickness of the second conductive layer can be set according to actual needs, for example, it can be more than 1 nm, more than 10 nm, more than 100 nm, more than 500 nm, or more than 1 μm, but it should not be too thick to avoid causing substantial increase in the overall thickness and cost of the Micro-LED chip.

In one embodiment, the LED chip structure includes a first doped semiconductor layer, an active layer and a second doped semiconductor layer that are stacked sequentially along a set direction. A side surface of the first doped semiconductor layer or the second doped semiconductor layer away from the active layer is the light emergence face.

In one embodiment, the first conductive layer forms an ohmic contact with the light emergence face of the LED chip structure, for example, forms an ohmic contact with the first doped semiconductor layer or the second doped semiconductor layer.

In one embodiment, the Micro-LED chip may include multiple LED chip structures, and the multiple LED chip structures are arranged in an array, i.e., forming an array of LED chips. Each LED chip structure can be used as one pixel point, or multiple adjacent LED chip structures can be used as one pixel point. Exemplarily, the multiple LED chip structures are divided into multiple groups, each group includes three blue LED chip structures, and different first metasurface conductive structure layers are respectively disposed on the three LED chip structures, so that the three pixel points corresponding to the three LED chip structures present three colors of blue, red and green respectively. Compared with the Micro-LED full-color display solution based on mass transfer technology and quantum dot film color conversion technology, the full-color display solution of the present application has many advantages such as a simple structure, low cost, a high yield rate, good process controllability, environmental protection and the like.

Further, the Micro-LED chip can also include a light isolation structure to better eliminate optical crosstalk between adjacent LED chip structures and improve display effects such as contrast and brightness of the Micro-LED chip. Taking the surface of the second doped semiconductor layer as the light emergence face as an example, the light isolation structure may include an ion implantation region, an isolation groove and a light-blocking structure distributed in the Micro-LED chip; the ion implantation region extends continuously at least from the top end surface of the second doped semiconductor layer to the inside of the first doped semiconductor layer, and is used for electrically isolating any two adjacent LED chip structures from each other; the entire isolation groove is located in the ion implantation region, an opening of the groove is disposed on the top end surface of the second doped semiconductor layer, and the bottom surface of the groove is located in the first doped semiconductor layer and higher than the bottom surface of the ion implantation region; the light-blocking structure is disposed in the isolation groove and used for preventing light from being transmitted between any two adjacent LED chip structures through the second doped semiconductor layer and the active layer.

The array of LED chips is realized by adopting an ion implantation isolation manner, and by opening the isolation groove in the ion implantation region and setting up the light-blocking structure in the isolation groove, the miniaturization of the chip can be better realized, the chip sidewall damage and dangling bonds caused by the etching process can be avoided, and the quantum efficiency and effective use area of the chip are ensured and improved, giving it better optical and electrical properties. Meanwhile, it can also effectively prevent light from being transmitted between adjacent chips in the array of LED chips, and eliminate optical crosstalk, thereby improving the display effects such as contrast and brightness of the array of LED chips. By placing the entire isolation groove in the ion implantation region, on one hand, the risk of damaging the semiconductor material due to over-etching during the making of the isolation groove can be further reduced, and on the other hand, the ion implantation region can also be utilized to electrically isolate the conductive filling material in the isolation groove from the semiconductor material in the structural layers such as the second doped semiconductor layer and the active layer, so as to ensure the normal working performance of the device.

The implanted ions used for forming the ion implantation region include H ions, F ions, N ions or O ions, etc., but are not limited thereto. Moreover, there may be one or more ion implantation regions. Illustratively, on the surface of the Micro-LED chip, the ion implantation region may be in a grid shape, and the region surrounded by each grid is a non-ion implantation region, which is used for making the LED chip structure. Correspondingly, there may be also one or more isolation grooves, and illustratively, they may also be presented as a grid-like structure on the surface of the Micro-LED chip.

The ion implantation region can be disposed around a corresponding non-ion implantation region, and an LED chip structure is formed in the corresponding non-ion implantation region. The dimensions of both the ion implantation region and the LED chip structure can be determined according to actual needs. Illustratively, the dimensions of the ion implantation region and the LED chip structure are 1 μm-50 μm. The dimensions of the ion implantation region and the LED chip structure mainly refer to the dimensions of the ion implantation region and the LED chip structure in a direction parallel to the layer plane of the LED chip structure, and can also be considered as the length and width or diameter thereof.

There is a certain distance between the inner wall of the isolation groove and the outer wall of the corresponding ion implantation region. That is, the ion implantation region has a certain wall thickness, which can be, for example, 100 nm-20 μm.

The Micro-LED chip may further include at least one thermally conductive dielectric layer, which continuously covers at least the side wall of the isolation groove and is located between the side wall of the isolation groove and the light-blocking structure; and the light-blocking structure includes a metal light isolation layer at least continuously covering the dielectric layer. By disposing the thermally conductive dielectric layer, on one hand the protection of the side walls of the isolation groove can be achieved, and on the other hand, the conductive filling material in the isolation groove can be further electrically isolated from the semiconductor material in the second doped semiconductor layer, the active layer and the like structure layers. Moreover, the thermally conductive dielectric layer can also be utilized to prevent ions from escaping from the ion implantation region when the metal light isolation layer is made by utilizing processes such as evaporation, thereby better ensuring the working performance of the device.

The material of the thermally conductive dielectric layer includes silicon oxide, silicon nitride, aluminum nitride, aluminum oxide, gallium oxide, titanium oxide or hafnium oxide, but is not limited thereto. The thickness of the thermally conductive dielectric layer may be 5 nm-500 nm.

Preferably, the Micro-LED chip includes a plurality of thermally conductive dielectric layers with different refractive indexes. The plurality of thermally conductive dielectric layers are at least sequentially stacked on the side wall of the isolation groove, and combined with the ion implantation region to form a distributed bragg reflector structure (DBR). The definition of the distributed bragg reflector structure is commonly known in the art, and the DBR is mainly an optical film composed of a low refractive index material and a high refractive index material through different stacking combinations. Illustratively, the low refractive index material can be selected from, but is not limited to, SiO₂, etc., and the high refractive index material can be selected from, but is not limited to, TiO₂, Ta₂O₅, ZrO₂, etc., and the thickness required for achieving the desired reflectivity is smaller when the refractive index difference between the materials is larger.

Specifically, after an ion implantation region is formed in a selected area of the LED chip structure through ion implantation, the refractive index of the semiconductor material will also change, thereby cooperating with the semiconductor material in the chip to form a light refraction interface, and then a DBR structure can be formed through the multiple dielectric layers with different refractive indexes that are alternately stacked on the side wall of the isolation groove, which can not only achieve side wall passivation to better ensure the stable electrical performance and long-term reliability of the optoelectronic chip, but also cooperate with the light-blocking structure to optically isolate and fully reflect the light ejected from the side wall of the optoelectronic chip, so that more light in the optoelectronic chip can be ejected from the front face, thereby better eliminating the problem of optical crosstalk and further improving the photoelectric conversion efficiency of the chip.

The material of the metal light isolation layer may include gold, titanium, aluminum, nickel, chromium, molybdenum or copper, but is not limited thereto. Preferably, the metal light isolation layer is formed of a metal or alloy that has both excellent reflective properties and electrically conductive properties, such as Al. The metal light isolation layer may be of a single-layer or multi-layer structure. Preferably, the thermal expansion coefficient of the thermally conductive dielectric material used for forming the thermally conductive dielectric layer is between the thermal expansion coefficient of the material constituting the metal light isolation layer and the thermal expansion coefficient of the material constituting the ion isolation region, and/or, the thermally conductive dielectric material has good bonding properties with both the material constituting the metal light isolation layer and the material constituting the ion isolation region. This not only helps to transfer the heat generated by the working of the chip away more quickly, but also makes the metal light isolation layer more firmly combined with the chip, preventing the metal light isolation layer from detaching from the chip structure under the influence of the heat generated by the chip after long-term working. The thermally conductive dielectric material may be selected from silicon nitride, aluminum nitride, etc., and is not limited thereto.

More preferably, the dielectric layer used for forming the distributed bragg reflector structure is formed of the thermally conductive dielectric material to have both light reflection and thermal conductivity functions.

The Micro-LED chip may further include a thermally conductive passivation layer. The thermally conductive passivation layer covers the surface of the LED chip structure and is thermally conductively connected to the metal light isolation layer. By utilizing the thermally conductive passivation layer, it can not only protect the surface of the array of LED chips, but also cooperate with the metal light isolation layer to form a thermal conductive path, which is more conducive to reducing the temperature of the array of LED chips and ensuring the working performance and stability of the array of LED chips. The material of the thermally conductive passivation layer may include aluminum nitride, boron nitride, or diamond, etc., but is not limited thereto.

In some instances, a local area of the thermally conductive passivation layer is filled into the isolation groove and is in direct contact with the metal light isolation layer. Moreover, in some instances, some windows can also be opened on the thermally conductive passivation layer for making electrodes that match the structure of each LED chip.

In some instances, the metal light isolation layer also extends to cover the surface of the LED chip structure and form a current expanding layer.

In the present application, the material of the LED chip structure includes group III-V compounds, and preferably group III nitrides, for example AlₓIn_{y}Ga_{1-x-y}N, wherein 1≥x≥0, 1≥y≥0, and 1≥(1−xy)≥0. The first doped semiconductor layer and the second doped semiconductor layer have different conductivity types. For example, the first doped semiconductor layer and the second doped semiconductor layer can be a N-type semiconductor layer and a P-type semiconductor layer respectively, and vice versa. The active layer may be a multiple quantum well layer. In addition, the LED chip structure may also include other structural layers commonly seen in the art, for example a buffer layer, etc. The materials, thicknesses, and the like of these structural layers can be selected or set according to manners known in the art, and will not be described one by one here anymore. Illustratively, the LED chip structure may be a GaN-based LED chip structure.

In the present application, the Micro-LED chip may also include a substrate, for example sapphire, Si, SiC, GaN substrates, etc., but is not limited thereto. In some instances, for example when the Micro-LED chip has a flip-chip structure, the substrate can also be removed.

Some embodiments of the present application further provide a method for preparing the Micro-LED chip, which includes:
making a LED chip structure; and
disposing a first conductive layer and a metasurface structure on the light emergence face of the LED chip structure, wherein the metasurface structure is configured to be stacked and/or integrated with the first conductive layer.

In one embodiment, a process such as metal organic chemical vapor deposition (MOCVD) or molecular beam epitaxy (MBE) can be utilized to sequentially grow the first doped semiconductor layer, the active layer, the second doped semiconductor layer, etc. on the substrate, so as to from the epitaxial structure of the Micro-LED chip, and then photolithography, etching and the like processes are utilized to make one or more of the LED chip structures in the epitaxial structure.

In one embodiment, the metasurface structure includes a first metasurface structure, and the preparation method specifically includes: when a first conductive layer is made on the light emergence face of the LED chip structure, forming a plurality of first pattern structures in the first conductive layer, and distributing a plurality of the first pattern structures along a direction parallel to the light emergence face, thereby forming the first metasurface structure.

Further, a continuous transparent dielectric layer can be formed on the first conductive layer by atomic layer deposition (ALD) or other physical/chemical deposition manners.

In one embodiment, the metasurface structure includes a second metasurface structure, and the preparation method specifically includes: disposing a transparent dielectric layer on the first conductive layer, forming a plurality of second pattern structures in the transparent dielectric layer, and distributing the plurality of second pattern structures in a direction parallel to the light emergence face, thereby forming the second metasurface structure.

Illustratively, a continuous metal layer with a thickness of less than 20 nm can be made on the light emergence face of the LED chip structure by evaporation or sputtering as the first conductive layer, and then a dielectric layer with a second metasurface structure is formed on the first conductive layer through atomic layer deposition (ALD) or other physical/chemical deposition manners.

In one embodiment, the metasurface structure includes a first metasurface structure and a second metasurface structure, and the preparation method specifically includes:
when a first conductive layer is made on the light emergence face of the LED chip structure, forming a plurality of first pattern structures in the first conductive layer, and distributing a plurality of the first pattern structures along a direction parallel to the light emergence face, thereby forming the first metasurface structure; and
disposing a transparent dielectric layer on the first conductive layer, forming a plurality of second pattern structures in the transparent dielectric layer, and distributing the plurality of second pattern structures in a direction parallel to the light emergence face, thereby forming the second metasurface structure.

In the present application, a patterned mask can be set on the light emergence face of the LED chip structure in advance, and then a metal or non-metal conductive material can be directly deposited on the light emergence face of the LED chip structure through physical/chemical deposition and the like manners, thereby obtaining the first conductive layer of the metasurface structure. Alternatively, a metal or non-metal conductive material can be directly deposited on the light emergence face of the LED chip structure through physical/chemical deposition and the like manners to form a continuous first conductive layer, and then photolithography, etching and the like processes are adopted to process the first conductive layer, so that the first conductive layer has a first metasurface structure. For the transparent dielectric layer, it can be enabled to have the second metasurface structure in a similar manner.

In the present application, after the making of the first conductive layer is completed, it is also possible to form ohmic contact between the first conductive layer and the light emergence face of the LED chip structure, i.e., the surface of the first doped semiconductor layer or the second doped semiconductor layer, through processes such as rapid annealing.

In one embodiment, the preparation method may further include: electrically binding the second face of the LED chip structure, i.e. a side surface opposite to the light emergence face with the LED driving mechanism through the second conductive layer.

Further, the side surface (second face) of the LED chip structure opposite to the light emergence face (first face) can be electrically bound with the LED driving mechanism through the second metasurface conductive structure layer. The second metasurface conductive structure layer includes the second conductive layer and a third metasurface structure. The third metasurface structure is formed on a side surface of the second conductive layer close to the LED chip structure or the second face of the LED chip structure.

Illustratively, a second conductive layer can be formed on the surface of the LED driving mechanism in advance, and a third metasurface structure can be made on the second conductive layer, and then the second conductive layer is bonded to the second face of the LED chip structure. Alternatively, a third metasurface structure can also be made on the second face of the LED chip structure, and then the second face of the LED chip structure is bonded with the LED driving mechanism through the second conductive layer. From the perspective of process controllability, the latter manner is more preferable.

The second conductive layer may also be called a metal bonding layer or metal adhesion layer, etc., and its material includes but is not limited to a combination of one or more of In, Sn, Ag, Au, etc. Alternatively, the second conductive layer may also be formed by adopting conductive glue or the like. However, from the perspective of ensuring bonding strength and thermal conductivity, the adoption of the former manner will achieve a better effect.

In one embodiment, the preparation method may further include the following steps.
firstly ion implantation treatment is conducted on the LED chip structure at least from the top end surface of the second doped semiconductor layer, and the ion implantation depth is allowed to reach the inside of the first doped semiconductor layer, so as to form an ion implantation region to electrically isolate multiple LED chip structures arranged in an array within the epitaxial structure by utilizing the ion implantation region, wherein the implanted ions include but are not limited to H ions, F ions, N ions or O ions, etc. Generally speaking, the ion implantation region is disposed around the non-ion implantation region, and the LED chip structure is made in the non-ion implantation region. The dimensions of the ion implantation region and the non-ion implantation region can be set to 1 μm-50 μm. In order to increase the effective utilization area of the epitaxial structure, the dimension of the non-ion implantation region should be as large as possible, while the dimension of the ion implantation region should be as small as possible within a reasonable range. This reasonable range should meet such conditions that electrical isolation between adjacent chip structures can be achieved and it is convenient for opening isolation grooves.

Secondly, the ion implantation region is etched at an etching depth that is less than the ion implantation depth which reaches the inside of the first doped semiconductor layer, so as to form an isolation groove in the ion implantation region, thereby at least isolate the second doped semiconductor layers and active layers of any two adjacent LED chip structures from each other.

Then, a light-blocking structure is disposed in the isolation groove to prevent light from being transmitted between any two adjacent LED chip structures through the second doped semiconductor layer and the active layer.

Illustratively, a patterned ion implantation mask can be preset on the surface of the LED chip structure, and the ion implantation can be performed by utilizing the mask. The ion implantation mask can be pre-made and then transferred to the surface of the LED chip structure, or it can be formed by coating a photoresist layer on the surface of the LED chip structure and then utilizing a photolithography process on the surface of the LED chip structure. The pattern and dimension of the ion implantation mask correspond to the shape and dimension of the ion implantation region, which can be determined according to actual needs. For example, the ion implantation region can be circular, square ring, or other regular or irregular shapes.

Illustratively, etching processes such as RIE, ECR, and ICP can be used for etching the ion implantation region to form the isolation groove. Further, by setting an etching mask on the ion implantation region and using the etching mask to perform the etching operation, the position, dimension and shape of the isolation groove can be more accurately controlled to avoid damage to the sidewalls of the chip structure. Preferably, the distance between the opening edge on the etching mask and the edge of the ion implantation region can be controlled to 100 nm-20 μm, so that the distance between the inner wall of the etched isolation groove and the outer wall of the corresponding ion implantation region is 100 nm-20 μm. In actual production, the spacing of the high-resistance ion implantation region can be accurately adjusted by changing the dimensions and the like of the aforementioned ion implantation mask and etching mask, thereby flexibly defining the characteristic dimension of the chip and realizing preparation of devices with dimensions ranging from several microns to hundreds of microns.

Further, the preparation method may further include:
making at least one thermally conductive dielectric layer, and allowing the thermally conductive dielectric layer to at least continuously cover the side wall of the isolation groove; and
making a metal light isolation layer, and allowing the metal light isolation layer to at least continuously cover the thermally conductive dielectric layer, so as to form the light-blocking structure.

In the aforementioned embodiments of the present application, the thermally conductive dielectric layer can be grown through processes such as atomic layer deposition (ALD), and its thickness can be set to 5 nm-500 nm.

Preferably, a plurality of alternately stacked thermally conductive dielectric layers with different refractive indexes can be formed at least on the side wall of the isolation groove, and the plurality of thermally conductive dielectric layers are combined with the ion implantation region to form a distributed bragg reflector structure.

Further, a thermally conductive passivation layer can be formed on the surface of the LED chip structure, and the thermally conductive passivation layer is thermally connected to the metal light isolation layer. The thermally conductive passivation layer can also be formed by growing through processes such as atomic layer deposition (ALD). Preferably, the thermally conductive passivation layer can cover the entire surface of the LED chip structure. Of course, if you want to make an electrode, etc., corresponding windows and the like can be opened in the thermally conductive passivation layer.

Further, the metal light isolation layer can also be extended to cover the surface of the LED chip structure to form a current expanding layer, which is also beneficial to improving the luminous uniformity of the array of LED chips.

By adopting the aforementioned solution, the problem of optical crosstalk of the device can be effectively eliminated, the luminous efficiency of the device can be improved, and meanwhile, the effective use area of the chip can be increased, and the damage effect of the material sidewall can be reduced, so as to achieve Micro-LED chips with smaller dimensions and better optical characteristics (e.g., resolution and brightness, etc.) and electrical characteristics.

Further, electrodes and the like that match the LED chip structure can also be made through well-known solutions in the art, so that the Micro-LED chip can work normally.

Obviously, compared with the solution of improving the light extraction efficiency and light extraction direction of the Micro-LED chips through the resonant cavity structure or lens system, and the solution of realizing full-color display through mass transfer or quantum dot film color conversion technology, the method of the present application is adapted for large-scale standard semiconductor processes, has significantly reduced process difficulty and higher controllability, is safer and more environmentally friendly, and has small structural changes of the device, making it suitable for lightweight applications with low cost, high yield rate and better device quality, which can better meet the application requirements suitable for ultra-high resolution display.

Additionally, the solution of the present application is also suitable for making micro-nano-sized optoelectronic devices such as Mini-LED chips.

Some embodiments of the present application further provides a Micro-LED device, which includes the Micro-LED chip. The Micro-LED device may be a lighting device, a display device, etc., but is not limited thereto.

The following describes the implementation of the present application through specific examples. Other advantages and effects of the present application can be easily understood by those skilled in the art from the content disclosed in this specification. The present application can also be implemented or applied through other different specific embodiments. Various details in this specification can also be modified or changed in various ways based on different viewpoints and applications without departing from the spirit of the present application.

When the embodiments of the present application are described in detail, for convenience of explanation, the cross-sectional views showing the device structure will not be partially enlarged according to the general scale, and the schematic diagrams are only examples, which shall not limit the claimed scope of the present application herein. The three-dimensional dimensions of length, width and depth should be included in actual making.

For convenience of description, spatial relationship words such as “below”, “underneath”, “under”, “inferior”, “above”, “on”, etc. may be used herein for describing the relationship of an element or feature shown in the figures to other elements or features. It will be understood that these spatially relationship words are intended to encompass other orientations of the device in use or operation in addition to the directions depicted in the figures. Moreover, when a layer is referred to as being “between” two layers, it can be the only layer between the two layers, or one or more intervening layers may also be present therebetween.

In the context of the present application, a structure described as having a first feature “on” a second feature may include an embodiment in which a first feature and a second feature form direct contact, and may also include an embodiment in which a further feature is formed between the first feature and the second feature, in such way the first feature and the second feature may not be in direct contact.

It should be noted that the illustrations provided in the present embodiments only illustrate the basic concept of the present application in a schematic manner, so the illustrations only show the components related to the present application and are not depicted based on the numbers, shapes and dimensions of components during actual implementation. The mode, number and proportion of each component during actual implementation can be changed at will, and its component layout pattern may be more complicated.

### Example 1

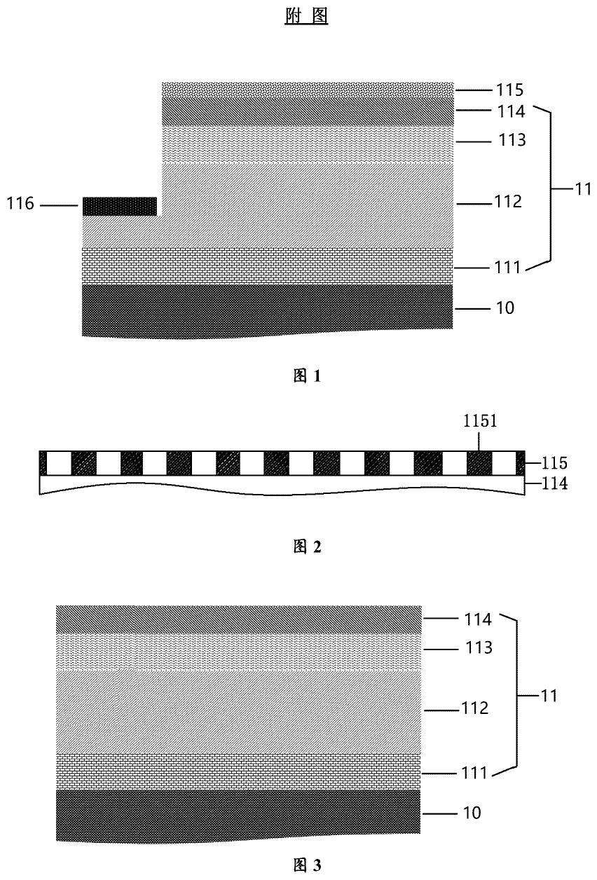

Please referring to FIG. 1, this example provides a Micro-LED chip, which includes a sapphire substrate 10 and an LED chip structure 11. The LED chip structure includes a AlₓGa₁₋ₓN (0≤x≤1) buffer layer 111, a N-type GaN layer 112, a GaN multiple quantum well active layer (GaN MQWs) 113 and a P-type GaN layer 114 grown sequentially on the substrate from bottom to top. The GaN MQWs layer 113 emits blue light with a wavelength of about 450 nm. Further, the surface of the P-type GaN layer 114 is the light emergence face of the LED chip structure, and a first metasurface conductive structure layer is further disposed on the surface of the P-type GaN layer 114. The first metasurface conductive structure layer is a p-type electrode 115, i.e., an Au/Ni metal layer (the aforementioned first conductive layer), which has a thickness of about 50 nm and has a first metasurface structure composed of a plurality of first pattern structures 1151 periodically arranged on the surface of the P-type GaN layer 114. As shown in FIG. 2, there are two kinds of first pattern structures, one of which is X-shaped (referred to as a X-shaped pattern structure for short) in a specified direction parallel to the light emergence face, and the other is a shape formed by rotating a Y shape by 90° clockwise (referred to as a variant Y-shaped pattern structure for short). The dimensions of both the X-shaped pattern structure and the variant Y-shaped pattern structure are both about 500 nm. They are alternately arranged along the specified direction. One X-shaped pattern structure and one Y-shaped pattern structure adjacent thereto are spaced 40 nm apart and form a unit. A plurality of the units are periodically arranged, and the periods in both the specified direction and the direction perpendicular to the specified direction are about 140 nm. Moreover, the Au/Ni metal layer forms ohmic contact with the P-type GaN layer 114. Meanwhile, the LED chip structure 11 has a mesa structure, and a Ti/Al/Ni/Au layer, or a conductive layer of indium tin oxide (ITO), indium (In), tin (Sn), silver (Ag), platinum (Pt), gold (Au), titanium (Ti), aluminum (Al), nickel (Ni), chromium (Cr), molybdenum (Mo) or copper (Cu) and the like materials can be adopted as its n-type electrode 116, and can form an ohmic contact with the N-type GaN layer 112. Compared with the Micro-LED chip that uses a continuous ITO conductive layer or a continuous Au/Ni metal layer with a thickness of less than 20 nm as a p-type electrode, the Micro-LED chip of this example adopts the first metasurface conductive structure layer, and thus emits green light with a wavelength of about 550 nm.

A method for making the Micro-LED chip includes the following steps.
S1. the AlN buffer layer 111, the N-type GaN layer 112, the multiple quantum well active layer 113 and the P-type GaN layer 114 are sequentially grow on the sapphire substrate with MOCVD, MBE or PECVD and the like manners to obtain the epitaxial wafer shown in FIG. 3.
S2. the P-type GaN layer 114, the GaN MQWs layer 113 and part of the N-type GaN layer 112 are patternically removed through photolithography, dry or wet etching processes and the like. That is, the P-type GaN layer 114 and the N-type GaN layer 112 are exposed after patterning to form the mesa structure. Then, an ohmic contact is formed on the surface of the N-type GaN layer 112 through metal film deposition, rapid annealing and the like processes. The ohmic-contact metal, i.e., the n-type electrode 116, can be Ti/Al/Ni/Au or a similar structure, the thickness of each layer does not exceed 500 nm, the rapid annealing temperature is 500° C.-1,000° C., and the annealing time does not exceed 180 s.
S3. a patterned evaporation mask is set on the top end surface of the P-type GaN layer 114, and then a Au/Ni metal is deposited on the top end surface of the P-type GaN layer 114 through evaporation to form a p-type electrode 115 with a first metasurface structure.

### Example 2

The structure of the Micro-LED chip provided in this example is basically the same as that in Example 1, except that: the p-type electrode adopts an Au/Ni metal layer with a thickness of about 10 nm, and the dimension and period of the first pattern structure in the first metasurface structure of the p-type electrode are also the same as those in Example 1.

Compared with the Micro-LED chip in which a continuous Au/Ni metal layer with a thickness of about 10 nm is used as the p-type electrode, the Micro-LED chip of this example adopts the first metasurface conductive structure layer, and thus emits green light with a wavelength of about 550 nm. Compared with the Micro-LED chip of Example 1, the luminous brightness of the Micro-LED chip of this example is significantly improved.

### Example 3

The structure of the Micro-LED chip provided in this example is basically the same as that in Example 2, except that: the p-type electrode is also covered with a continuous and transparent silicon oxide (SiO₂) film with a thickness of about 1 μm.

Compared with the Micro-LED chip of Example 2, the Micro-LED chip of this example has better luminous uniformity.

### Example 4

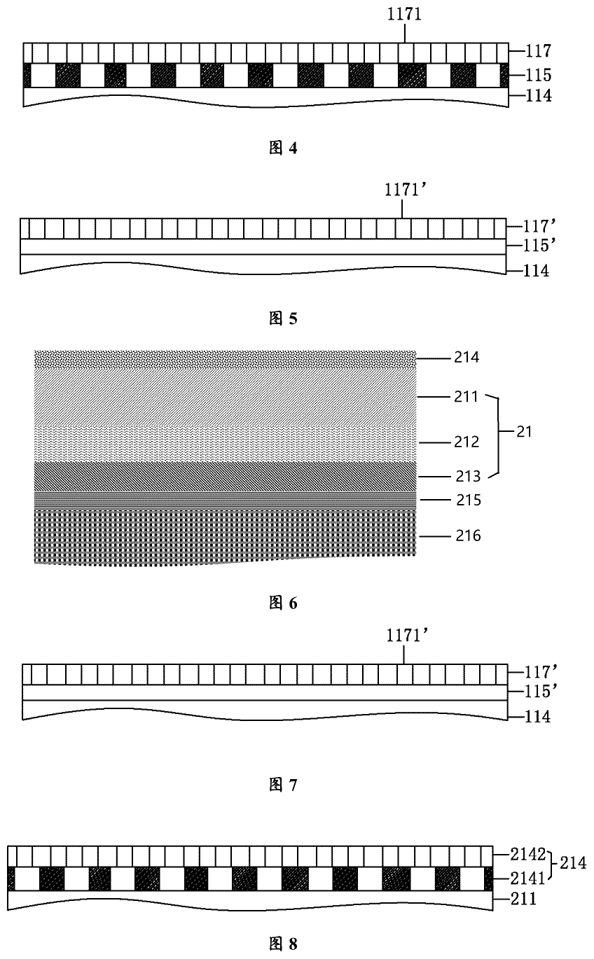

The structure of the Micro-LED chip provided in this example is basically the same as that in Example 1, except that: Referring to FIG. 4, the p-type electrode 115 is also covered with a transparent silicon oxide (SiO₂) film 117 with a thickness of about 1 μm. The SiO₂ film has a second metasurface structure composed of a plurality of second pattern structures 1171 periodically arranged on the upper surface of the p-type electrode. The second pattern structure is a circular pattern structure with a variant F-shaped through hole embedded in the center thereof. The diameter of the circular pattern structure is 100 nm. In a specified direction parallel to the light emergence face, the shape of the variant F-shaped through hole is a shape formed by rotating a F-shape by 30° clockwise, and the lateral dimension of it is about 30 nm and the longitudinal dimension of it is about 40 nm. The periods in both the specified direction and the direction perpendicular to the specified direction are about 50 nm.

A method for making the Micro-LED chip is also basically the same as that in Example 1, except that it also includes the following steps.
S4. a continuous SiO₂ film is deposited on the p-type electrode by adopting ALD or the like processes, and then the SiO₂ film is patterned by adopting photolithography and dry etching processes to form the second metasurface structure.

Compared with Example 1, the Micro-LED chip of this example adopts the first metasurface structure and the second metasurface structure, and thus, not only it emits green light with a wavelength of about 550 nm, but also the collimation and light extraction of the device are significantly improved. In particular, the color displayed by the device has higher saturation and contrast.

### Example 5

The structure of the Micro-LED chip provided in this example is basically the same as that in Example 4, except that: the first metasurface structure is the same as the second metasurface structure in Example 4, and the second metasurface structure is the same as the first metasurface structure in Example 4.

The working performance of the Micro-LED chip of this example is similar to that of Example 4, but the saturation and contrast of the color displayed during working are reduced to a certain extent.

### Example 6

The structure of the Micro-LED chip provided in this example is basically the same as that in Example 4, except that: The second pattern structure has two shapes of a variant K shape and a variant L shape. In a specified direction, the variant K shape is a shape formed by rotating a K shape by 45° counterclockwise, and the variant L shape is a shape formed after flipping the L shape in a mirror image manner. The dimensions of the two pattern structures are both about 100 nm. They are alternately arranged along the specified direction. One variant K-shaped pattern structure and one variant L-shaped pattern structure adjacent thereto are spaced about 30 nm apart from each other and form a unit. A plurality of the units are arranged periodically, and the periods in both the specified direction and the direction perpendicular to the specified direction are about 130 nm. The light emitted by the Micro-LED chip is mainly green light with a wavelength of about 550 nm, but both the collimation and light extraction efficiency of the device are inferior to those of the device in Example 4.

### Example 7

The structure of the Micro-LED chip provided in this example is basically the same as that in Example 2, except that: The p-type electrode is also covered with a transparent silicon oxide (SiO₂) film with a thickness of about 1 μm. The SiO₂ film has a second metasurface structure composed of a plurality of second pattern structures periodically arranged on the upper surface of the p-type electrode. The second pattern structure is a regular hexagonal pattern structure with an H-shaped through hole embedded in the center thereof. The diameter of the regular hexagonal pattern structure is 80 nm. The lateral and longitudinal dimensions of the H-shaped through holes are both about 35 nm. In the specified direction, every two adjacent regular hexagonal pattern structures are spaced about 60 nm apart from each other and form a unit. A plurality of the units are arranged periodically. The periods in both the specified direction and the direction perpendicular to the specified direction are about 140 nm.

Compared with Examples 2 and 3, the Micro-LED chip of this example adopts the first metasurface structure and the second metasurface structure, and thus, not only it emits green light with a wavelength of about 550 nm, but also the collimation and light extraction of the device are both significantly improved. In particular, the color displayed by the device also has higher saturation and contrast.

### Example 8

The structure of the Micro-LED chip provided in this example is basically the same as that in Example 4, except that: Referring to FIG. 5, the Au/Ni metal layer 115′ is continuous and has a thickness of about 10 nm; and, in the second metasurface structure of the SiO₂ film 117′, in a specified direction parallel to the light emergence face, the second pattern structure 1171′ is an ellipse with a long axis of about 120 nm and parallel to the specified direction, and a short axis of about 80 nm. A V-shaped through hole and an X-shaped through hole are respectively formed on two sides of the short axis. The dimension of the V-shaped through hole is about 25 nm, and the dimension of the X-shaped through hole is about 40 nm. The V-shaped through hole and the X-shaped through hole are spaced about 50 nm apart from each other. Two adjacent ellipses are spaced about 60 nm apart from each other and form a unit. A plurality of the units are periodically arranged, the period in the specified direction is about 180 nm, and the period in the direction perpendicular to the specified direction is about 140 nm. The Micro-LED chip of this example adopts the second metasurface structure, and thus it emits red light with a wavelength of about 650 nm, so that the light can be ejected from the active region with low loss, directivity, and high collimation and light extraction efficiency.

### Example 9

The structure of the Micro-LED chip provided in this example is basically the same as that in Example 8, except that: In the second metasurface structures of the SiO₂ thin film, in a specified direction parallel to the light emergence face, the second pattern structure has four shapes, i.e., variant z-shaped, variant T-shaped, variant M-shaped and P-shaped pattern structures. The dimensions of these four pattern structures are all about 150 nm. The variant z-shaped and the variant T-shaped pattern structures are alternately arranged along the specified direction. The variant M-shaped and P-shaped pattern structures are also alternately arranged along the specified direction, the P-shaped and variant Z-shaped pattern structures are alternately arranged in the direction perpendicular to the specified direction, and the variant M-shaped and variant T-shaped pattern structures are alternately arranged in the direction perpendicular to the specified direction. A total of four pattern structures, i.e., adjacent variant Z-shaped, variant T-shaped, variant M-shaped and P-shaped pattern structures, form one unit, wherein the spacings between two adjacent pattern structures in the specified direction and between two adjacent pattern structures in the direction perpendicular to the specified direction are both about 50 nm. A plurality of the units are periodically arranged, and the periods in the specified direction and the direction perpendicular to the specified direction are both about 200 nm. The Micro-LED chip of this example adopts the second metasurface structure, so that although it still emits blue light, its collimation, brightness and luminous uniformity etc. are significantly improved compared with those of the control product that does not adopt the second metasurface structure.

### Example 10

Please referring to FIGS. 6-7, this example provides a Micro-LED chip including an LED chip structure 21. The LED chip structure includes an N-type GaN layer 211, a GaN multiple quantum well active layer (GaN MQWs) 212 and a P-type GaN layer 213. The GaN MQWs layer 212 emits blue light with a wavelength of about 450 nm. Further, the surface of the N-type GaN layer 211 is the light emergence face of the LED chip structure, and a first metasurface conductive structure layer 214 is also disposed on the surface of the N-type GaN layer 211. The first metasurface conductive structure layer includes an n-type electrode 2141 and a transparent silicon oxide layer 2142 stacked on the n-type electrode 2141. The n-type electrode 2141 and the transparent silicon oxide layer 2142 respectively have the same first metasurface structure and the second metasurface structure as those in Example 4, and the n-type electrode 2141 forms an ohmic contact with the N-type GaN layer 211. Meanwhile, the P-type GaN layer 213 is bonded to a driving substrate 216 through a metal adhesion layer 215 (i.e., the aforementioned second conductive layer), and is electrically connected to a CMOS (complementary metal oxide semiconductor) or TFT (thin film field effect transistor in the driving substrate) driving circuit in the driving substrate.

A method for making the Micro-LED chip includes the following steps.
S1. the AlN buffer layer, the N-type GaN layer, the multiple quantum well active layer and the P-type GaN layer are sequentially grown on a silicon substrate with MOCVD, MBE or PECVD and the like manners to obtain an epitaxial wafer with a structure similar to that shown in FIG. 3.
S2. the P-type GaN layer of the epitaxial wafer is adhered to a temporary substrate of the same dimension through temporary bonding and the like processes. A silicon or sapphire substrate can be adopted as the temporary substrate. The adhesion force includes but is not limited to an electrostatic force, and an adhesion force provided by an adhesive material such as photoresist that can be released without damage, so that the epitaxial wafer can be separated from the temporary substrate without damage through a debonding process.
S3. the silicon substrate in the epitaxial wafer is removed by laser stripping, thinning, grinding and the like processes, then the AlN buffer layer is removed by dry etching or wet corrosion processes, and part of the N-type GaN layer is removed.
S4. a first metasurface conductive structure layer is prepared on the remaining N-type GaN layer surface in a manner similar to that of Example 4.
S5. the LED chip structure in the device structure obtained in step S4 is separated from the temporary substrate through a debonding process.
S6. the P-type GaN layer is bonded to a driving substrate through a metal adhesion layer.

When the Micro-LED chip is used, the brightness of the Micro-LED chip can be controlled by applying different electrical signals to the CMOS or TFT driving circuit.

### Example 11

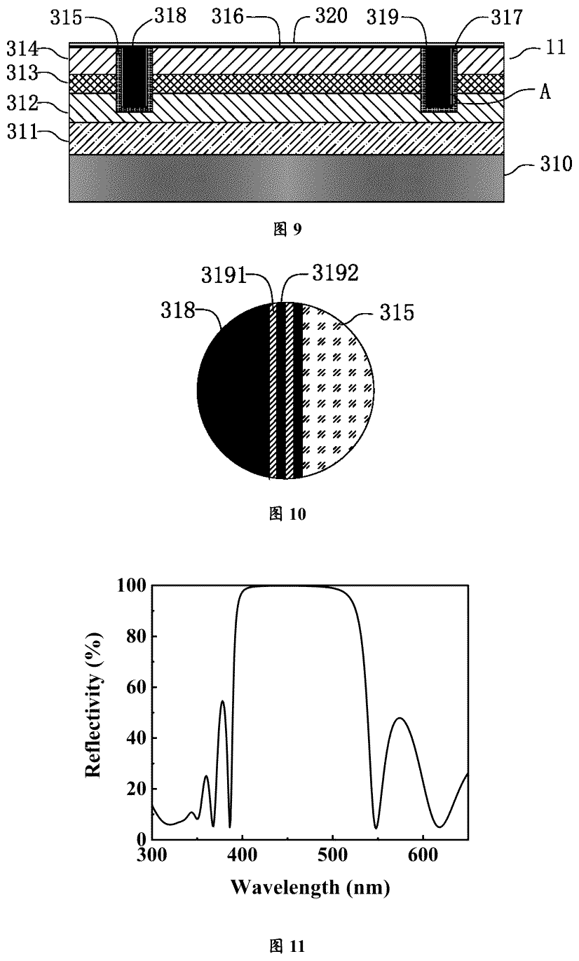

Please referring to FIG. 8, the structure of the Micro-LED chip provided in this example is basically the same as that in Example 9, except that: a third metasurface structure 217 is also formed on a side surface of the P-type GaN layer 213 away from the N-type GaN layer, for reflecting light emitted from the active region to the P-type GaN layer. The third metasurface structure is composed of a plurality of third pattern structures 2171 that are periodically arranged. The third pattern structures are of two shapes of an equilateral triangle and a variant equilateral triangle. The side lengths of the two shapes of the pattern structures are both about 100 nm, and the two shapes are alternately arranged along a specified direction parallel to the side surface of the P-type GaN layer 213 away from the N-type GaN layer. A X-shaped through hole is embedded in the center of the equilateral triangle pattern structure. The variant X-shaped through hole is a shape obtained by rotating a X shape by 45° clockwise. The length of each line of the X shape is about 60 nm. The variant Z-shaped through hole is embedded in the center of the variant equilateral triangle pattern structure. The variant equilateral triangle is a shape obtained after rotating the equilateral triangle by 90° clockwise around a specified point. The variant Z-shaped through hole is a shape obtained by rotating the Z shape by 45° clockwise, and the length of each line of the Z shape is also about 60 nm. The midpoint of one side of each equilateral triangle pattern structure and a vertex of an adjacent variant equilateral triangle pattern structure intersect at the designated point and form a unit. A plurality of the units are arranged periodically, the period in the specified direction is about 300 nm, and the period in the direction perpendicular to the specified direction is about 200 nm. Compared with Examples 4 and 10, the Micro-LED chip of this example has higher brightness, and its collimation is also improved more obviously.

A method for making the Micro-LED chip is basically the same as that in Example 10, except that it also includes the following steps.
S5X: After the step S5 is completed, the exposed surface of the P-type GaN layer is patterned through photolithography and dry etching processes to form a third metasurface structure, and then step S6 is performed.

### Example 12

Please referring to FIG. 9, this example provides an epitaxial structure of a Micro-LED chip, which includes an AlN buffer layer 311, an N-type GaN layer 312, a multiple quantum well active layer 313 and a P-type GaN layer 314 sequentially grown on a sapphire substrate 310. The multiple quantum well active layer can emit blue light with a central wavelength of about 450 nm. The epitaxial structure includes ion implantation regions 315 and a plurality of non-ion implantation regions distributed along a layer plane direction. Any two adjacent non-ion implantation regions are electrically isolated by the ion implantation region, and one LED chip structure 316 is fabricated in each non-ion implantation region. Each LED chip structure 316 can be used as a pixel point. That is, there are multiple pixel points in the Micro-LED chip. Meanwhile, an isolation groove 317 is also opened in the ion implantation region to isolate the P-type GaN layer and the multiple quantum well active layer of two adjacent LED chip structures from each other. Moreover, a light-blocking structure is also disposed in the isolation groove for preventing light from being transmitted between two adjacent Micro-LED chip structures through the P-type GaN layer 314 and the multiple quantum well active layer 313. The light-blocking structure includes one or more layers of opaque metal light isolation layers 318, of which the material includes gold (Au), titanium (Ti), aluminum (Al), nickel (Ni), chromium (Cr), Molybdenum (Mo), copper (Cu), etc. or an alloy thereof. The metal light isolation layer covers the inner wall of the isolation groove, and is mainly used for blocking and reflecting the light reflected by the multiple quantum well active layer, and blocking the transmission path of the light between adjacent Micro-LED chip structures. A thermally conductive dielectric layer 319 is also disposed between the metal light isolation layer and the inner wall of the isolation groove. As shown in FIG. 10, the thermally conductive dielectric layer has a structure of 8 pairs of TiO₂/SiO₂ composite layers. The total thickness of the thermally conductive dielectric layer is about 895.2 nm, wherein the TiO₂ layers 3191 and the SiO₂ layers 3192 are alternately stacked to form a distributed bragg reflector structure. The thickness of each TiO₂ layer is about 41.1 nm, and the thickness of each SiO₂ layer is about 70.8 nm. The reflectivity of the thermally conductive dielectric layer for light of different wavelengths is shown in FIG. 11. On one hand, the thermally conductive dielectric layer can passivate the inner wall of the isolation groove and electrically isolate the metal light isolation layer from the inner wall of the isolation groove. On the other hand, it can cooperate with the metal light isolation layer (e.g., a metal aluminum layer) to more completely eliminate the problem of optical crosstalk. Meanwhile, it can also be used as a transition layer between the ion implantation region of a doped GaN material and the metal light isolation layer to strengthen the bonding force between the metal light isolation layer and the wall of the isolation groove, and to cooperate with the metal light isolation layer to build a new heat conduction channel for the Micro-LED chip. Meanwhile, the metal light isolation layer also continuously extends to cover the surfaces of adjacent LED chip structures, thereby forming a current expanding layer. In addition, the current expanding layer is also covered with a transparent dielectric layer 320, which is in direct contact with the metal light isolation layer, and of which the material may include but is not limited to silicon oxide, titanium oxide, etc. The current expanding layer and the transparent dielectric layer of each LED chip structure cooperate to form a first metasurface conductive structure. Moreover, the first metasurface conductive structure layers on the surfaces of three adjacent LED chip structures are different. For example, the first metasurface conductive structure layers on the surfaces of the three LED chip structures are the same as those in Examples 1, 7, and 8 respectively. That is, they emit green light, red light, and blue light respectively to achieve full-color display. In order to achieve the same first metasurface conductive structure layer as that in Example 1, the current expanding layer on the surface of the corresponding LED chip structure can be patterned. In order to achieve the same first metasurface conductive structure layer as those in Examples 7 and 8, the thickness of the current expanding layer on the surface of the corresponding LED chip structure can be reduced to be less than 20 nm.

As an improved solution, referring to Examples 9 and 10, the sapphire substrate, or the sapphire substrate and the AlN buffer layer are removed, the metal adhesion layer 215 (i.e., the aforementioned second conductive layer) is bonded to the driving substrate, and the N-type GaN layer is electrically connected to the CMOS (complementary metal oxide semiconductor) or TFT (thin film field effect transistor) driving circuit in the drive substrate. By applying different electrical signals to the CMOS or TFT driving circuit to control the brightness of different pixels, three pixel units of red, green and blue with different brightness can be mixed into one color unit, thus enabling applications in the field of full-color display.

A method for preparing the Micro-LED chip can include the following steps.
S1. an AlN buffer layer, an N-type GaN layer, a multiple quantum well active layer and a P-type GaN layer are sequentially grown on a sapphire substrate with MOCVD, MBE, PECVD and the like manners to obtain an epitaxial wafer.
S2. a patterned ion implantation mask is formed through photolithography and the like processes, wherein the material of the ion implantation mask includes but is not limited to photoresist, silicon oxide, silicon nitride, metal, etc. The ion implantation mask is used as a blocking layer, and the epitaxial structure in the epitaxial wafer is subjected to ion implantation, thereby regulating the area and/or shape of the light emergence region of the Micro-LED chip. The depth of ion implantation must at least penetrate the P-type GaN layer, and preferably reach the inside of the N-type GaN layer. The types of ions as implanted include but are not limited to H ions, F ions, N ions, O ions, etc. The dimension of the finally formed ion implantation region is 1 μm-50 μm, and the dimension of the non-ion implantation region is 1 μm-50 μm. From the perspective of a top view, the ion implantation region is preferably set around the non-ion implantation region. Each non-ion implantation region is used for forming one LED chip structure. This step uses ion implantation for electrical isolation. Compared with the electrical isolation conducted by the etching process, it has the advantages of less damage and high control accuracy.
S3. an etching mask is set on the ion implantation region, and a through hole is opened on the etching mask. The dimension of the through hole is smaller than that of the ion implantation region. Preferably, the distance between the edge of the through hole and the edge of the ion implantation region is 100 nm-20 μm, so as to reduce the sidewall damage of the chip as much as possible. Then, the ion implantation region is etched through the through the through hole of the etching mask by dry etching processes such as atomic layer etching (ALE), ion beam etching (IBE), inductively coupled plasma etching (ICP), etc. The etching depth is smaller than or equivalent to the ion implantation depth, but is preferably smaller than the ion implantation depth, and is particularly preferably into the interior of the N-type GaN layer to form the isolation groove. By performing dry etching in the ion implantation region, this step can not only effectively avoid damage to the sidewalls caused by the etching process, improve photoelectric conversion efficiency, but also form a narrower etching isolation region, and particularly can effectively isolate the light among pixels in the Micro-LED chip and eliminate the optical crosstalk effect.
S4. a thermally conductive dielectric layer is formed on the side wall of the isolation groove through atomic layer deposition (ALD) and the like processes. In some instances, the thermally conductive dielectric layer can also be utilized to completely cover the inner wall of the isolation groove. Further, an opaque metal material is deposited on the thermally conductive dielectric layer to form a metal light isolation layer. The light-blocking structure mainly formed by the metal light isolation layer can effectively reduce optical crosstalk between each pixel point. The isolation groove can also be filled with the metal light isolation layer. Then, the metal light isolation layer continuously extends to cover the surface of the adjacent LED chip structure, thereby forming a current expanding layer. For the current expanding layers on the surfaces of different LED chip structures, they can be thinned and patterned respectively. Thereafter, a transparent dielectric layer is deposited on the metal light isolation layer as a passivation layer to passivate the surface of the metal light isolation layer, and at the same time it also serves as a thermal conductive layer of the Micro-LED chip. In particular, the transparent dielectric layer on the surface of part of the LED chip structure can also be patterned, so that the current expanding layer and the transparent dielectric layer on the surface of each LED chip structure cooperate to form the aforementioned first metasurface conductive structure layer.

The aforementioned examples merely illustrate the principles and efficacy of the present application, rather than limiting the present application. Anyone skilled in the art can modify or change the aforementioned examples without departing from the spirit and scope of the present application. Therefore, all equivalent modifications or changes made by those of ordinary skills in the art without departing from the spirit and technical idea disclosed in the present application should still be covered by the claims of the present application.

1. A Micro-LED chip, comprising an LED chip structure, wherein: the Micro-LED chip further comprises a first metasurface conductive structure layer, and the first metasurface conductive structure layer comprises:
a first conductive layer, wherein the first conductive layer is electrically bonded to a light emergence face of the LED chip structure; and
a metasurface structure, wherein the metasurface structure is configured to be stacked and/or integrated with the first conductive layer, and is at least used for regulating an emergence angle and/or wavelength of light ejected from the light emergence face.

2. The Micro-LED chip according to claim 1, wherein: the metasurface structure comprises a first metasurface structure, the first conductive layer comprises a plurality of first pattern structures, the plurality of first pattern structures are distributed in a direction parallel to the light emergence face and form the first metasurface structure; wherein the first conductive layer comprises a metal or non-metal conductive layer.

3. The Micro-LED chip according to claim 1, wherein: the first conductive layer comprises a metal or non-metal conductive layer; the metal conductive layer has a thickness below 20 nm and extends continuously in a direction parallel to the light emergence face.

4. The Micro-LED chip according to claim 2, wherein: a material of the metal conductive layer comprises a combination of any one or more of indium, tin, silver, platinum, gold, titanium, aluminum, nickel, chromium, molybdenum and copper; and/or a thickness of the metal conductive layer is 0.1 nm-20 nm, or the thickness of the metal conductive layer is greater than 20 nm;
and/or, the material of the non-metal conductive layer comprises ITO; and/or, a thickness of the non-metal conductive layer is 1 nm-500 nm.

5. The Micro-LED chip according to claim 2, wherein: each first pattern structure comprises an X-shaped pattern structure and a variant Y-shaped pattern structure; in a specified direction parallel to the light emergence face, the variant Y-shaped pattern structure is in a shape formed by rotating a Y shape by 90° clockwise, and dimensions of the X-shaped pattern structure and the variant Y-shaped pattern structure are both 1 nm-1 μm; and the X-shaped pattern structure and the variant Y-shaped pattern structure are alternately arranged along the specified direction, and each X-shaped pattern structure and the variant Y-shaped pattern structure adjacent thereto are spaced 1-500 nm apart from each other and forms a unit, multiple units are periodically arranged, and periods in the specified direction and a direction perpendicular to the specified direction are both 1 nm-1 μm.

6. The Micro-LED chip according to claim 1, wherein: the first metasurface conductive structure layer further comprises a transparent dielectric layer stacked on the first conductive layer.

7. The Micro-LED chip according to claim 6, wherein: the metasurface structure comprises a second metasurface structure, the transparent dielectric layer comprises a plurality of second pattern structures, and the plurality of second pattern structures are distributed in a direction parallel to the light emergence face and form the second metasurface structure.

8. The Micro-LED chip according to claim 7, wherein the metasurface structure comprises:
a first metasurface structure, wherein the first metasurface structure is formed in the first conductive layer and at least used for regulating one of the emergence angle and wavelength of the light ejected from the light emergence face; and
the second metasurface structure, wherein the second metasurface structure is at least used for regulating the other one of the emergence angle and wavelength of the light ejected from the light emergence face;
and/or, in the direction parallel to the light emergence face, a dimension of each second pattern structure is 1 nm-1 μm;
and/or each second pattern structure comprises a circular pattern structure with a variant F-shaped through hole embedded in a center of the circular pattern structure, and in a specified direction parallel to the light emergence face, the variant F-shaped through hole is in a shape formed by rotating a F shape by 30° clockwise, a dimension of the variant F-shaped through hole is 1-200 nm, a plurality of circular pattern structures are arranged periodically, and periods in the specified direction and a direction perpendicular to the specified direction are both 1 nm-1 μm;
alternatively, each second pattern structure comprises a variant K-shaped pattern structure and a variant L-shaped pattern structure, in a specified direction parallel to the light emergence face, the variant K-shaped-shape pattern structure is formed by rotating a K shape by 45° counterclockwise, the variant L-shaped pattern structure is a shape formed by flipping a L shape in a mirror image manner, the variant K-shaped pattern structure and the variant L-shaped pattern structure are alternately arranged along the specified direction, each of the variant K-shaped pattern structures and one variant L-shaped pattern structure adjacent thereto is spaced 1-200 nm apart from each other and forms a unit, a plurality of the units are periodically arranged, and the periods in the specified direction and [[the direction perpendicular to the specified direction are both 1-500 nm;
alternatively, each second pattern structure comprises a regular hexagonal pattern structure with an H-shaped through hole embedded in the center thereof, a dimension of the H-shaped through hole is 1-200 nm, in a specified direction parallel to the light emergence face every two adjacent regular hexagonal pattern structures are spaced 1-200 nm apart from each other and form a unit, a plurality of the units are arranged periodically, and the periods in the specified direction and the direction perpendicular to the specified direction are both 1-1,000 nm;
alternatively, each second pattern structure comprises an elliptical pattern structure, the elliptical pattern structure has a long axis dimension of 1-1,000 nm and a short axis dimension of 1-1,000 nm, the long axis dimension is parallel to a specified direction on the light emergence face, a V-shaped through hole and an X-shaped through hole are respectively formed on two sides of a short axis, dimensions of the V-shaped through hole and the X-shaped through hole are 1-500 nm, the V-shaped through hole and the X-shaped through hole are spaced 1-500 nm apart from each other, each two adjacent elliptical pattern structures are spaced 1-500 nm apart from each other and form a unit, a plurality of the units are periodically arranged, and the periods in the specified direction and the direction perpendicular to the specified direction are 1-1,000 nm;
alternatively, each second pattern structure comprises a variant Z-shaped pattern structure, a variant T-shaped pattern structure, a variant M-shaped pattern structure, and a P-shaped pattern structure, the variant Z-shaped pattern structure and the variant T-shaped pattern structure are alternately arranged along a specified direction parallel to the light emergence face, and the variant M-shaped pattern structure and the P-shaped pattern structure are also alternately arranged along the specified direction, the P-shaped pattern structure and the variant Z-shaped pattern structure are alternately arranged in a direction perpendicular to the specified direction, the variant M-shaped pattern structure and the variant T-shaped pattern structure are alternately arranged in the direction perpendicular to the specified direction, each of the variant Z-shaped pattern structures and one variant T-shaped pattern structure, one variant M-shaped pattern structure and one P-shaped pattern structure that are adjacent thereto form a unit, and spacing between any two pattern structures in each of the units in the specified direction and the direction perpendicular to the specified direction is 1-200 nm; a plurality of the units are arranged periodically, and the periods in the specified direction and the direction perpendicular to the specified direction are 1-1,000 nm.

9. The Micro-LED chip according to claim 6, wherein: a material of the transparent dielectric layer comprises a combination of any one or more of silicon oxide, silicon nitride, aluminum nitride, aluminum oxide, gallium oxide, titanium oxide, and hafnium oxide; and/or the transparent dielectric layer has a thickness of 0.1 nm-1 μm.

10. The Micro-LED chip according to claim 1, further comprising a second metasurface conductive structure layer, wherein the LED chip structure has a first face and a second face opposite to the first face, the first face is the light emergence face, and the second face is electrically bound with a LED driving mechanism through a second conductive layer.

11. The Micro-LED chip according to claim 10, wherein: the second face of the LED chip structure is electrically bound with the LED driving mechanism through the second metasurface conductive structure layer, the second metasurface conductive structure layer comprises the second conductive layer and a third metasurface structure, the third metasurface structure is disposed on a side surface of the second conductive layer close to the LED chip structure or the second face of the LED chip structure, and is at least used for reflecting light emitted by the LED chip structure toward the second metasurface conductive structure layer; and
the third metasurface structure comprises a plurality of third pattern structures distributed in a direction parallel to the second face, and a dimension of the third pattern structure is 1 nm-1 μm; and the third pattern structure comprises an equilateral triangle pattern structure and a variant equilateral triangle pattern structure, the equilateral triangle pattern structure and the variant equilateral triangle pattern structure are alternately arranged along a specified direction parallel to the second face, wherein a variant X-shaped through hole is embedded in a center of the equilateral triangle pattern structure, the variant X-shaped through hole is in a shape obtained by rotating a X shape by 45° clockwise, a variant Z-shaped through hole is embedded in a center of the variant equilateral triangle pattern structure, the variant equilateral triangle pattern structure is a shape obtained by rotating an equilateral triangle around a designated point by 90° clockwise, the variant Z-shaped through hole is in a shape obtained by rotating a Z-shape by 45° clockwise, a line length of the variant X-shaped through hole and the variant Z-shaped through hole is 1 nm-500 nm; a midpoint of one side of each of the equilateral triangle pattern structures and a vertex of an adjacent one of the equilateral triangle pattern structure intersect at the designated point and form a unit., and a plurality of the units are periodically arranged, and periods in the specified direction and a direction perpendicular to the specified direction are 1 nm-1 μm.

12. The Micro-LED chip according to claim 1, wherein: the LED chip structure comprises a first doped semiconductor layer, an active layer and a second doped semiconductor layer, the first doped semiconductor layer, the active layer and the second doped semiconductor layer are stacked sequentially along a set direction, a side surface of the first doped semiconductor layer or the second doped semiconductor layer far away from the active layer is the light emergence face; and/or the first conductive layer forms an ohmic contact with the light emergence face of the LED chip structure; and/or the LED chip structure comprises a GaN-based LED chip structure.

13. A method for preparing the Micro-LED chip according to claim 1, comprising:
making a LED chip structure; and
disposing a first conductive layer and a metasurface structure on the light emergence face of the LED chip structure, wherein the metasurface structure is configured to be stacked and/or integrated with the first conductive layer.

14. The method according to claim 13, wherein the metasurface structure comprises a first metasurface structure, and the method specifically comprises: when the first conductive layer is made on the light emergence face of the LED chip structure, forming a plurality of first pattern structures in the first conductive layer, and distributing the plurality of first pattern structures along a direction parallel to the light emergence face, thereby forming the first metasurface structure;
alternatively, the metasurface structure comprises a second metasurface structure, and the method specifically comprises: disposing a transparent dielectric layer on the first conductive layer, forming a plurality of second pattern structures in the transparent dielectric layer, and distributing the plurality of second pattern structures in the direction parallel to the light emergence face, thereby forming the second metasurface structure;
alternatively, the metasurface structure comprises the first metasurface structure and the second metasurface structure, and the method specifically comprises:
when the first conductive layer is made on the light emergence face of the LED chip structure, forming the plurality of first pattern structures in the first conductive layer, and distributing the plurality of first pattern structures along a direction parallel to the light emergence face, thereby forming the first metasurface structure; and
disposing a transparent dielectric layer on the first conductive layer, forming the plurality of second pattern structures in the transparent dielectric layer, and distributing the plurality of second pattern structures in the direction parallel to the light emergence face, thereby forming the second metasurface structure.

15. The method according to claim 13, further comprising: electrically binding a side surface of the LED chip structure opposite to the light emergence face with a LED driving mechanism through a second metasurface conductive structure layer; wherein the second metasurface conductive structure layer comprises a second conductive layer and a third metasurface structure formed on a side surface of the second conductive layer close to the LED chip structure or on a side surface of the LED chip structure opposite to the light emergence face.

16. A Micro-LED device, comprising the Micro-LED chip according to claim 1.

17. The Micro-LED chip according to claim 3, wherein: a material of the metal conductive layer comprises a combination of any one or more of indium, tin, silver, platinum, gold, titanium, aluminum, nickel, chromium, molybdenum and copper; and/or thickness of the metal conductive layer is 0.1 nm-20 nm, or the thickness of the metal conductive layer is greater than 20 nm;
and/or, the material of the non-metal conductive layer comprises ITO; and/or, a thickness of the non-metal conductive layer is 1 nm-500 nm.

18. The Micro-LED chip according to claim 2, wherein: the first metasurface conductive structure layer further comprises a transparent dielectric layer stacked on the first conductive layer.

19. The Micro-LED chip according to claim 3, wherein: the first metasurface conductive structure layer further comprises a transparent dielectric layer stacked on the first conductive layer.

20. The Micro-LED chip according to claim 18, wherein: the metasurface structure comprises a second metasurface structure, the transparent dielectric layer comprises a plurality of second pattern structures, and the plurality of second pattern structures are distributed in a direction parallel to the light emergence face and form the second metasurface structure.
